(19) United States
(12) Patent Application Publication
(10) Pub. No.: US 2018/0005849 A1
(43) Pub. Date: Jan. 4, 2018

(54) SUBSTRATE TREATING APPARATUS

(71) Applicant: SEMES CO., LTD., Chungcheongnam-do (KR)

(72) Inventors: Ji-hwan LEE, Gyeonggi-do (KR); Jungbong CHOI, Gyeonggi-do (KR); Chan Young HEO, Chungcheongnam-do (KR); Pil Kyun HEO, Chungcheongnam-do (KR); Byung Man KANG, Chungcheongnam-do (KR)

(21) Appl. No.: 15/632,768

(22) Filed: Jun. 26, 2017

(30) Foreign Application Priority Data
Jun. 30, 2016 (KR) 10-2016-0082469

(51) Int. Cl. H01L 21/67; B08B 3/00; B23B 31/28; H01L 21/687

(52) U.S. Cl. CPC H01L 21/67051; H01L 21/68785; H01L 21/68728; B08B 3/00; H01L 21/6708; B23B 31/28; H01L 21/6715

(57) ABSTRACT

Disclosed is a substrate treating apparatus. The substrate treating apparatus includes a spin head, a support shaft connected to a lower portion of the spin head to support the spin head, a pin located on an upper surface of the spin head to support the substrate and having a space in the interior thereof, and a nozzle member configured to supply a liquid to the substrate located on the spin head.

### CROSS-REFERENCE TO RELATED APPLICATIONS

A claim for priority under 35 U.S.C. §119 is made to Korean Patent Application No. 10-2016-0082469 filed Jun. 30, 2016, in the Korean Intellectual Property Office, the entire contents of which are hereby incorporated by reference.

### BACKGROUND

Embodiments of the inventive concept described herein relate to a substrate treating apparatus.

In order to manufacture a semiconductor, various processes such as photolithography, etching, ashing, ion implantation, thin film deposition, and cleaning are performed on a substrate. The processes may include at least one process of applying a liquid to an upper surface of the substrate.

The process of applying the liquid to the upper surface of the substrate may be performed by rotating the substrate while the liquid is supplied to the upper surface of the substrate. The liquid supplied to the upper surface of the substrate spreads out to the whole parts of the upper surface of the substrate due to a centrifugal force by the rotation. Then, a spin head may be rotated while the substrate is supported by the spin head. A support pin and a chucking pin are located in the spin head to support the substrate.

### SUMMARY

In accordance with an aspect of the inventive concept, there is provided a substrate treating apparatus including a spin head, a support shaft connected to a lower portion of the spin head to support the spin head, a pin located on an upper surface of the spin head to support the substrate and having a space in the interior thereof, and a nozzle member configured to supply a liquid to the substrate located on the spin head.

The space formed in the interior of the pin may extend to a lower end of the pin.

The space formed in the interior of the pin may be vacuumed.

The pin may include a support pin configured to support a bottom surface of the substrate, and a chucking pin configured to support a side surface of the substrate.

A thickness, between the space and an outer surface of the chucking pin, of a part of the chucking pin, which faces a part which faces the substrate may be larger than a thickness of a part of the chucking pin, which contacts the substrate.

The chucking pin may have a reinforcement part protruding outwards at a part of the chucking pin, which faces a part which faces the substrate.

A communication part configured to provide a path along which the liquid applied to the substrate may flow to an outside is formed at an upper end of the chucking pin.

The communication part may have a shape of a recess that is concave downwards from an upper end of the chucking pin.

The communication part may be a hole formed at an upper end of the chucking pin.

In accordance with another aspect of the inventive concept, there is provided a substrate treating apparatus including a spin head, a support pin located on an upper surface of the spin head to support a bottom surface of the substrate, a chucking pin located in the spin head to support a side surface of the substrate and having a space in the interior thereof, a support shaft connected to a lower portion of the spin head to support the spin head, and a nozzle member configured to supply a liquid to the substrate located on the spin head.

In accordance with another aspect of the inventive concept, there is provided a substrate treating apparatus including a spin head, a support pin located on an upper surface of the spin head to support a bottom surface of the substrate and having a space in the interior thereof, a chucking pin located in the spin head to support a side surface of the substrate, a support shaft connected to a lower portion of the spin head to support the spin head, and a nozzle member configured to supply a liquid to the substrate located on the spin head.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a side view illustrating a substrate treating apparatus according to an embodiment of the inventive concept;

FIG. 2 is a sectional view of the support pin of FIG. 1;

FIG. 3 is a view illustrating a support pin according to another embodiment;

FIG. 4 is a sectional view of the chucking pin of FIG. 1;

FIG. 5 is a view illustrating a chucking pin according to another embodiment; and

FIG. 6 are views illustrating a chucking pin according to another embodiment; and

FIG. 7 are views illustrating a chucking pin according to another embodiment.

### DETAILED DESCRIPTION

Hereinafter, exemplary embodiments of the inventive concept will be described in more detail with reference to the accompanying drawings. The embodiments of the inventive concept may be modified in various forms, and the scope of the inventive concept should not be construed to be limited to the following embodiments. The embodiments of the inventive concept are provided to describe the inventive concept for those skilled in the art more completely. Accordingly, the shapes of the components of the drawings are exaggerated to emphasize clearer description thereof.

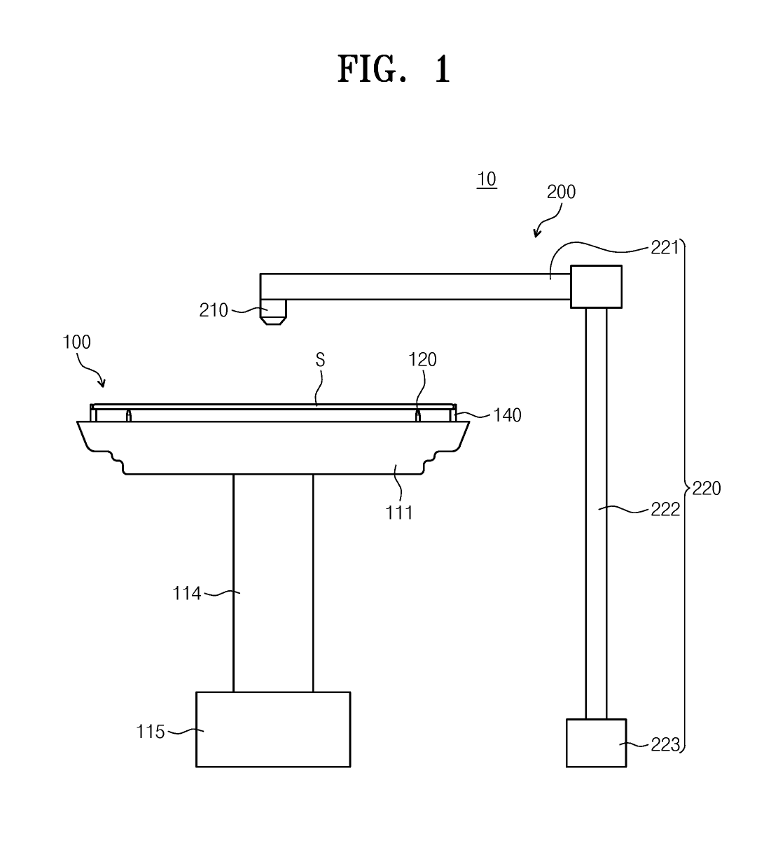

FIG. 1 is a side view illustrating a substrate treating apparatus according to an embodiment of the inventive concept.

Referring to FIG. 1, the substrate treating apparatus 100 includes a support member 100 and a nozzle member 200.

The support member 100 supports a substrate S during a process. The support member 100 includes a spin head 111, a support shaft 114, and a driving part 115.

The spin head 111 supports the substrate S. An upper surface of the spin head 111 may be substantially circular. The upper surface of the spin head 111 may have a diameter that is larger than that of the substrate S, and a lower surface of the spin head 111 may have a diameter that is smaller than the upper surface of the spin head 111. Further, a side surface of the spin head 111 may be inclined such that a diameter of the side surface of the spin head 111 becomes smaller as it goes from the upper surface to the lower surface of the spin head 111.

Pins 120 and 140 for supporting the substrate S are provided on the upper surface of the spin head 111. The pins 120 and 140 may include a support pin 120 and a chucking pin 140. The support pin 120 protrudes upwards from the upper surface of the spin head 111, and an upper end of the support pin 120 supports a bottom surface of the substrate S. A plurality of support pins 120 may be provided on the upper surface of the spin head 111 to be spaced apart from each other. As an example, at least three support pins 120 may be provided to be disposed in a ring shape.

The chucking pin 140 protrudes upwards from the upper surface of the spin head 111, and supports a side portion of the substrate S. When the spin head 111 is rotated, the chucking pins 140 prevent the substrate S from deviating laterally from the spin head 111 by a centrifugal force. A plurality of chucking pins 140 may be provided along a peripheral area of the upper surface of the spin head 111 to be spaced apart from each other. As an example, at least three chucking pins 140 may be provided to be combined with each other so as to be disposed in a ring shape. The chucking pins 140 are disposed to form a ring shape, a diameter of which is larger than the diameter of the ring shape formed by the support pins 120 with respect to the center of the spin head 111. The chucking pins 140 may be linearly moved along a radial direction of the spin head 111. When the substrate S is loaded or unloaded, the chucking pins 140 are linearly moved along a radial direction of the substrate S to be spaced apart from or contact a side surface of the substrate S.

The support shaft 114 is connected to a lower portion of the spin head 111 to support the spin head 111. The support shaft 114 may have a shape of a hollow shaft. The driving part 115 is provided at a lower end of the support shaft 114. The driving part 115 generates a rotational force that may rotate the support shaft 114.

The nozzle member 200 supplies a liquid to an upper surface of the substrate S.

The nozzle member 200 includes a liquid supply nozzle 210 and a nozzle moving part 220.

The liquid supply nozzle 210 supplies a liquid to the upper surface of the substrate S. The liquid supplied from the liquid supply nozzle 210 may be a chemical used for treating a substrate. As an example, the chemical may be an etching liquid such as hydrofluoric acid or a cleaning liquid. Further, the liquid supplied from the liquid supply nozzle 210 may be an organic solvent. As an example, the organic solvent may be isopropyl alcohol (IPA). Further, the liquid supplied from the liquid supply nozzle 210 may be deionized water.

The nozzle moving part 220 moves the liquid supply nozzle 210. The nozzle moving part 220 includes an arm 221, a support shaft 222, and a driving part 223. The liquid supply nozzle 210 is located at an end of the arm 221. The support shaft 222 is connected to an opposite end of the arm 221. The support shaft 222 receives power from the driving part 223, and moves an ejection head 310 connected to the arm 222 by using the power.

Hereinafter, a case in which spaces are formed in the interiors of the support pin 120 and the chucking pin 140 will be described as an example. However, a space may be formed in the interior of only one of the support pin 120 and the chucking pin 140.

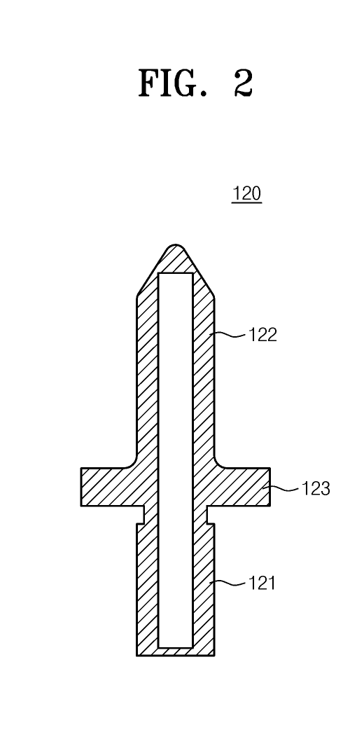

FIG. 2 is a sectional view of the support pin of FIG. 1.

Referring to FIG. 2, the support pin 120 includes a pin installation part 121 and a pin support part 122.

The pin installation part 121 is provided at a lower portion of the support pin 120. The pin installation part 121 may have a column shape. As an example, the pin installation part 121 may have various shapes such as a cylindrical column or a polygonal column. The pin installation part 121 allows the support pin 120 to be installed in the spin head 111 in a manner in which the pin installation part 121 is inserted into an upper side of the spin head 111.

The pin support part 122 extends upwards from an upper end of the pin installation part 121. The pin support part 122 may have a column shape. As an example, the pin support part 122 may have various shapes such as a cylindrical column or a polygonal column. A cross-sectional area of an upper side of the pin support part 122 may be smaller than that of a lower side of the pin support part 122. As an example, the cross-sectional area of the pin support part 122 may become smaller as it goes to the upper side. A whole part or a portion of the pin support part 122 is exposed to the upper side of the spin head 111 such that an upper end of the pin support part 122 supports a bottom surface of the substrate.

The support pin 120 may have a pin fixing part 123 at a portion at which the pin installation part 121 and the pin support part 122 are connected to each other. The pin fixing part 123 may extend radially from an outer surface of the support pin 120. An outer periphery of the pin fixing part 123 may have shapes, such as a circle or a polygon. The pin fixing part 123 may be located on an upper surface of the spin head 111 or inside the spin head 111 to prevent the support pin 120 from fluctuating upwards and downwards.

The support pin 120 has a hollow shape in which a space is formed in the interior thereof. The inner space may be formed at an upper portion of the support pin 120. As an example, the inner space may be formed in the pin support part 122. Further, the inner space may extend from an upper portion to a lower portion of the support pin 120. For example, the inner space may extend along the pin installation part 121 and the pin support part 122. The inner space may be filled with air, an inert gas, or the like. A degree by which the substrate is treated by a liquid depends on temperature. This is caused by the fact that the reactivity of the liquid and the substrate varies according to temperature. Accordingly, the temperature changes for areas of the substrate, a treatment degree by the liquid also changes for the areas of the substrate so that the uniformity of the substrate treatment deteriorates. In the substrate treating apparatus according to the inventive concept, an inner space is formed in the support pin 120 so that a heat transfer degree between the substrate and the support pin 120 decreases. Accordingly, a difference between the temperature of a part of the substrate, which contacts the support pin 120, and a peripheral area thereof decreases so that the uniformity of the substrate treatment may be improved. Further, the inner space may be in a vacuum state. If the inner space is vacuumed, the heat conduction by air or the like may be additionally interrupted.

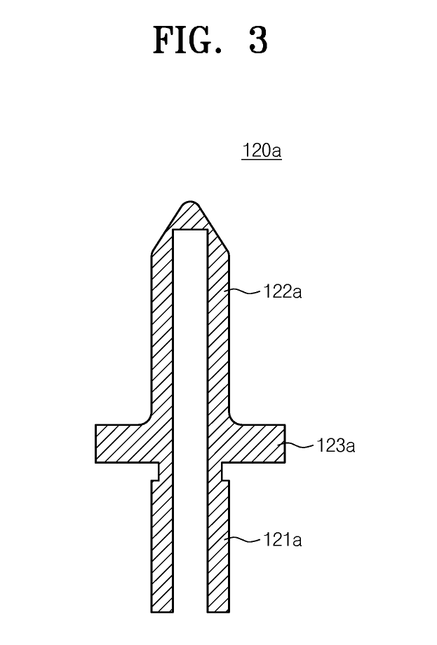

FIG. 3 is a view illustrating a support pin according to another embodiment.

Referring to FIG. 3, the support pin 120 includes a pin installation part 121a and a pin support part 122a.

A space is formed inside the support pin 120a and the support pin 120a extends to a lower end thereof such that the lower end of the support pin 120a has an opened shape. Further, similarly to the support pin 120 of FIG. 2, a pin fixing part 123a may be formed in the support pin 120a. Because a configuration of the support pin 120a is similar to that of the support pin 120 of FIG. 2 except that the space formed in the support pin 120a extends to a lower end of the support pin 120a, a repeated description will be omitted.

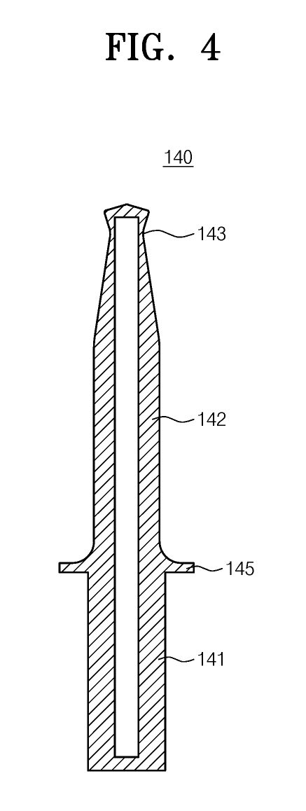

FIG. 4 is a sectional view of the chucking pin of FIG. 1.

Referring to FIG. 4, the chucking pin 140 includes an installation part 141 and a support part 142.

The installation part 141 is provided at a lower portion of the chucking pin 140. The installation part 141 may have a column shape. As an example, the installation part 141 may have various shapes such as a cylindrical column or a polygonal column. The installation part 141 allows the chucking pin 140 to be installed in the spin head 111 in a manner in which the pin installation part 121 is inserted into an upper side of the spin head 111. Further, the installation part 141 may be connected to an apparatus for driving the chucking pin 140.

The support part 142 extends upwards from an upper end of the installation part 141. The support part 142 may have a column shape. As an example, the support part 142 may have various shapes such as a cylindrical column or a polygonal column. A whole part or a portion of the support part 142 is exposed to the upper side of the spin head 111, and an upper side of the support part 142 supports a side surface of the substrate or a portion of a side surface and a bottom surface of the substrate.

A support recess 143 for supporting the substrate is formed at an upper portion of the support part 142. The support recess 143 is shaped to support a side surface of the substrate or a portion of a side surface and a bottom surface of the substrate. As an example, the support recess 143 may have an inwardly concave recessed shape or a stepped shape.

The chucking pin 140 may have a fixing part 145 at a portion at which the installation part 141 and the support part 142 are connected to each other. The fixing part 145 may extend radially from an outer surface of the chucking pin 140. An outer periphery of the fixing part 145 may have shapes, such as a circle or a polygon. The fixing part 145 may be located on an upper surface of the spin head 111 or inside the spin head 111 to prevent the chucking pin 140 from fluctuating upwards and downwards.

The chucking pin 140 has a hollow shape in which a space is formed in the interior thereof. The inner space may be formed at an upper portion of the chucking pin 140. As an example, the inner space may be formed in the support part 142. Further, the inner space may extend from an upper portion to a lower portion of the chucking pin 140. For example, the inner space may extend along the installation part 141 and the support part 142. The inner space may be filled with air, an inert gas, or the like. A degree by which the substrate is treated by a liquid depends on temperature. This is caused by the fact that the reactivity of the liquid and the substrate varies according to temperature. Accordingly, the temperature changes for areas of the substrate, a treatment degree by the liquid also changes for the areas of the substrate so that the uniformity of the substrate treatment deteriorates. In the substrate treating apparatus according to the inventive concept, an inner space is formed in the chucking pin 140 so that a heat transfer degree between the substrate and the chucking pin 140 decreases. Accordingly, a difference between the temperature of a part of the substrate, which contacts the chucking pin 140, and a peripheral area thereof decreases so that the uniformity of the substrate treatment may be improved. Further, the inner space may be in a vacuum state. If the inner space is vacuumed, the heat conduction by air or the like may be additionally interrupted.

A thickness between the interior space and the outer surface of the chucking pin 140 may be different for different areas. In detail, a thickness, between the space and an outer surface of the chucking pin, of a part of the chucking pin 140, which faces the part which faces the substrate may be larger than a thickness of a part of the chucking pin 140, which contacts the substrate. In a process of rotating the spin head 111, a radially outward force is applied to the chucking pin 140 by the substrate, and thus the chucking pin 140 may be damaged. Meanwhile, in the substrate treating apparatus according to the inventive concept, a thickness of a part of the chucking pin 140, which faces a part which contacts the substrate, may be larger than a thickness of a part of the chucking pin 140, which contacts the substrate, and thus the chucking pin 140 may be prevented from being damaged by the force.

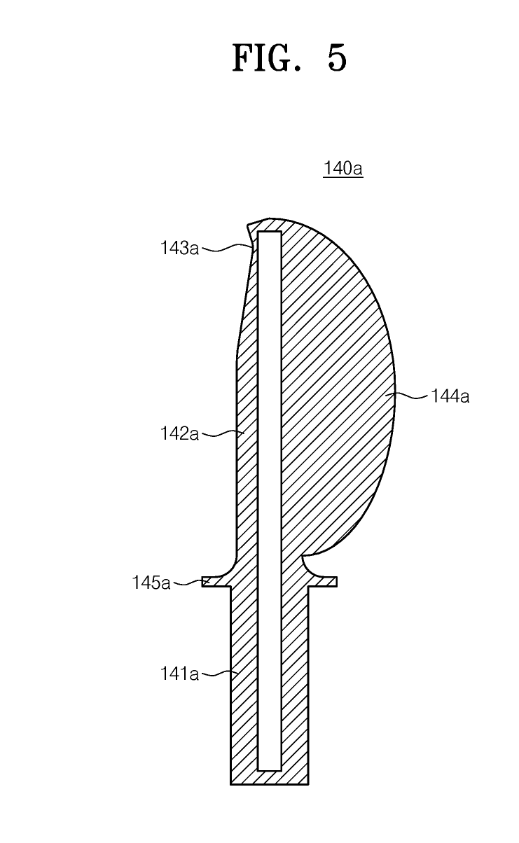

FIG. 5 is a view illustrating a chucking pin according to a third embodiment.

Referring to FIG. 5, the chucking pin 140a includes an installation part 141a and a support part 142a.

A space is formed inside the chucking pin 140a, and a reinforcement part 144a is formed in the installation part 141a. The reinforcement part 144a is formed at parts of the chucking pin 140a, which contacts and faces the substrate. The reinforcement part 144a has an outwardly protruding shape, and increases a thickness between the inner space and an outer surface of the chucking pin 140a. Accordingly, even though a force is applied to the chucking pin 140a in a process of rotating the spin head 111, the chucking pin 140a may be prevented from being damaged.

Because the configurations of the installation part 141a and the support part 142a and the facts that the support recess 143a and the fixing part 145a may be formed, except that the reinforcement part 144a is provided in the chucking pin 140 are similar to those of the chucking pin 140 of FIG. 4, a repeated description thereof will be omitted.

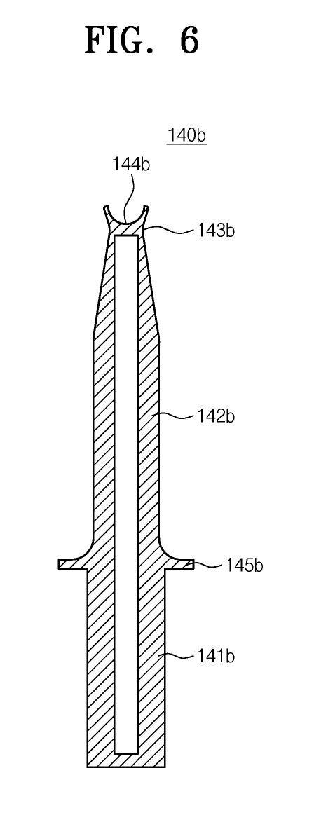

FIG. 6 is a view illustrating a chucking pin according to a third embodiment.

Referring to FIG. 6, the chucking pin 140b includes an installation part 141b and a support part 142b.

A communication part 144b is formed at an upper end of the chucking pin 140b. The communication part 144b has a shape of a recess that is recessed downwards from an upper end of the chucking pin 140b, a shape of a hole formed at an upper end of the chucking pin 140b, or the like. A lower end of the communication part 144b is located adjacent to the support recess 143b. Accordingly, if the chucking pin 140b supports the substrate, the communication part 144b may be adjacent to the upper surface of the substrate. The communication part 144b faces a radial direction. Accordingly, one side of the communication part 144b is located at a part of the chucking pin 140b, which contacts the substrate, and an opposite side of the communication part 144b faces an outside of the spin head 111. The communication part 144b restrains the chucking pin 140b from hampering movement of a liquid applied on the substrate to the outside. Accordingly, the communication parts 144b prevents a deviation between the amounts of the liquids residing on a substrate between a part of the substrate, which is adjacent to the chucking pin 140b and a peripheral portion thereof to improve a uniformity of the substrate treatment.

Because the configurations of the installation part 141b and the support part 142b and the fact that the fixing part 145b may be formed, except that the communication part 144b is provided in the chucking part 140b are similar to those of the chucking pins 140 and 140a of FIGS. 4 and 5, a repeated description thereof will be omitted. Further, when the communication part 144b and the reinforcement part 144a according to the embodiment of FIG. 5 are provided together, the communication part 144b extends radially to an end of the reinforcement part 144a at a part of the communication part 144b, which contacts the substrate.

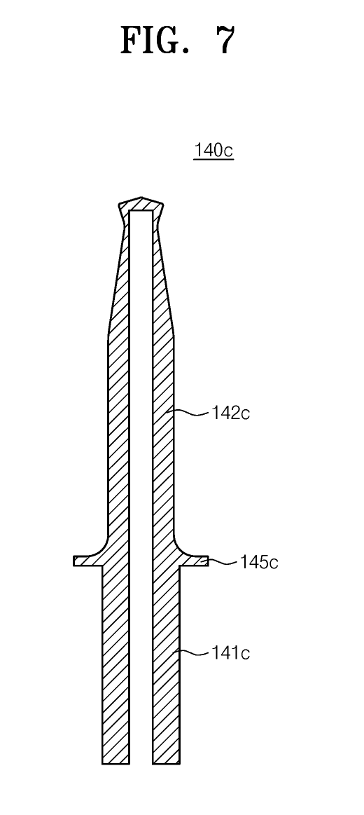

FIG. 7 is a view illustrating a chucking pin according to a fourth embodiment.

Referring to FIG. 7, the chucking pin 140c includes an installation part 141c and a support part 142c.

A space is formed inside the chucking pin 140c and the chucking pin 140c extends to a lower end, and a lower end of the chucking pin 140c has an opened shape. Further, a fixing part 145c may be formed in the chucking pin 140c similarly to the chucking pins 140, 140a, and 140b of FIGS. 4 to 6. Because the configurations of the chucking pin 140c are similar to those of the chucking pins 140, 140a, and 140b of FIGS. 4 to 6 except for the fact that the space formed in the chucking pin 140s extends to a lower end of the chucking pin 140c, a repeated description thereof will be omitted.

According to an embodiment of the inventive concept, a substrate treating apparatus that efficiently treats a substrate may be provided.

According to an embodiment of the inventive concept, a substrate treating apparatus that reduces a deviation between temperatures for areas of a substrate may be provided.

According to an embodiment of the inventive concept, a substrate treating apparatus that improves a uniformity of treatments for areas of a substrate may be provided.

The above description exemplifies the inventive concept. Furthermore, the above-mentioned contents describe the exemplary embodiment of the inventive concept, and the inventive concept may be used in various other combinations, changes, and environments. That is, the inventive concept can be modified and corrected without departing from the scope of the inventive concept that is disclosed in the specification, the equivalent scope to the written disclosures, and/or the technical or knowledge range of those skilled in the art. The written embodiment describes the best state for implementing the technical spirit of the inventive concept, and various changes required in the detailed application fields and purposes of the inventive concept can be made. Accordingly, the detailed description of the inventive concept is not intended to restrict the inventive concept in the disclosed embodiment state. Furthermore, it should be construed that the attached claims include other embodiments.

What is claimed is:

1. A substrate treating apparatus comprising:
a spin head;
a support shaft connected to a lower portion of the spin head to support the spin head;
a pin located on an upper surface of the spin head to support the substrate and having a space in the interior thereof; and
a nozzle member configured to supply a liquid to the substrate located on the spin head.

2. The substrate treating apparatus of claim 1, wherein the space formed in the interior of the pin extends to a lower end of the pin.

3. The substrate treating apparatus of claim 1, wherein the space formed in the interior of the pin is vacuumed.

4. The substrate treating apparatus of claim 1, wherein the pin comprises:
a support pin configured to support a bottom surface of the substrate; and
a chucking pin configured to support a side surface of the substrate.

5. The substrate treating apparatus of claim 4, wherein a thickness, between the space and an outer surface of the chucking pin, of a part of the chucking pin, which faces a part which faces the substrate is larger than a thickness of a part of the chucking pin, which contacts the substrate.

6. The substrate treating apparatus of claim 4, wherein the chucking pin has a reinforcement part protruding outwards at a part of the chucking pin, which faces a part which faces the substrate.

7. The substrate treating apparatus of claim 4, wherein a communication part configured to provide a path along which the liquid applied to the substrate flows to an outside is formed at an upper end of the chucking pin.

8. The substrate treating apparatus of claim 7, wherein the communication part has a shape of a recess that is concave downwards from an upper end of the chucking pin.

9. The substrate treating apparatus of claim 7, wherein the communication part is a hole formed at an upper end of the chucking pin.

10. A substrate treating apparatus comprising:
a spin head;
a support pin located on an upper surface of the spin head to support a bottom surface of the substrate;
a chucking pin located in the spin head to support a side surface of the substrate and having a space in the interior thereof;
a support shaft connected to a lower portion of the spin head to support the spin head; and
a nozzle member configured to supply a liquid to the substrate located on the spin head.

11. A substrate treating apparatus comprising:
a spin head;
a support pin located on an upper surface of the spin head to support a bottom surface of the substrate and having a space in the interior thereof;
a chucking pin located in the spin head to support a side surface of the substrate;
a support shaft connected to a lower portion of the spin head to support the spin head; and
a nozzle member configured to supply a liquid to the substrate located on the spin head.
